(19) United States
(12) Patent Application Publication
(10) Pub. No.: US 2022/0275217 A1
(43) Pub. Date: Sep. 1, 2022

(54) FILLER PARTICLE HAVING MORPHOLOGICAL ADHESION PROMOTER SHELL ON CORE

(71) Applicant: Infineon Technologies AG, Neubiberg (DE)

(72) Inventors: Stefan SCHWAB, Regensburg (DE); Edmund RIEDL, Wald (DE)

(73) Assignee: Infineon Technologies AG, Neubiberg (DE)

(21) Appl. No.: 17/585,996

(22) Filed: Jan. 27, 2022

(30) Foreign Application Priority Data
Feb. 26, 2021 (DE) 10 2021 104 671.8

(51) Int. Cl. C09C 3/06; H01L 23/18; H01L 23/29; H01L 23/31

(52) U.S. Cl. CPC C09C 3/063; H01L 23/18; H01L 23/291; H01L 23/3142

(57) ABSTRACT

Filler particle for a composite is disclosed. In one example, the filler particle comprises a core, and a shell which at least partially covers the core and has a morphological adhesion promoter.

### CROSS-REFERENCE TO RELATED APPLICATION

This Utility Patent application claims priority to German Patent Application No. 10 2021 104 671.8, filed Feb. 26, 2021, which is incorporated herein by reference.

### BACKGROUND

### Technical Field

Various embodiments relate generally to a filler particle, a composite, an electronic device, a method of manufacturing filler particles, and a method of manufacturing a composite.

### Description of the Related Art

A conventional package may comprise an electronic component mounted on a chip carrier such as a leadframe, may be electrically connected by a bond wire extending from the chip to the chip carrier, and may be molded using a mold compound as an encapsulant.

Delamination of constituents of a package may be an issue. Similar issues may occur in other devices, in particular in other electronic devices.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a filler particle according to an exemplary embodiment.

FIG. 2 illustrates a composite according to an exemplary embodiment.

FIG. 3 illustrates a flowchart of a method of manufacturing filler particles according to an exemplary embodiment.

FIG. 4 illustrates a flowchart of a method of manufacturing a composite according to an exemplary embodiment.

FIG. 5 illustrates an electronic device according to an exemplary embodiment.

FIG. 6 illustrates a composite according to an exemplary embodiment.

FIG. 7 illustrates a cross-sectional view of a package as an example for an electronic device according to an exemplary embodiment to be mounted on a mounting structure.

### DETAILED DESCRIPTION

There may be a need for enabling a proper bonding strength of matter.

According to an exemplary embodiment, a filler particle (and in particular a set of a plurality of such filler particles, for instance at least 100 such filler particles) for a composite is provided, wherein the filler particle comprises a core, and a shell which at least partially covers the core and has a morphological adhesion promoter.

According to another exemplary embodiment, a composite is provided which comprises a matrix (in particular comprising a resin), and filler particles in the matrix, wherein at least part of the filler particles comprises a core being at least partially covered by a shell having a morphological adhesion promoter.

According to another exemplary embodiment, an electronic device is provided which comprises at least one functional body, and a composite comprising filler particles having the above mentioned features and covering or enclosing at least part of the at least one functional body.

According to still another exemplary embodiment, a method of manufacturing filler particles is provided, wherein the method comprises at least partially covering a core of each of the filler particles by a shell, and forming the shell with a morphological adhesion promoter.

According to still another exemplary embodiment, a method of manufacturing a composite is provided, wherein the method comprises manufacturing filler particles by carrying out a method of manufacturing filler particles having the above-mentioned features, and embedding the filler particles in a matrix (in particular comprising a resin).

According to an exemplary embodiment, filler particles are provided which may have a central core and a shell surrounding at least part of the core and thus forming at least part of an exterior surface of the respective filler particle. Advantageously, the exterior shell of the filler particles comprises a morphological adhesion promoter which, in view of its morphology, promotes adhesion between the filler particles and surrounding medium, such as for example a matrix surrounding the filler particles. For example, the morphological adhesion promoter may be a porous structure covering or coating the core or part thereof, which improves or enhances adhesion with medium in an environment of the filler particles. Descriptively speaking, such a porous structure or other kind of morphology of the shell may increase the contact area between filler particles and surrounding matrix or medium and may therefore have a positive impact on the adhesion properties within a composite composed of, at least, the filler particles and the matrix.

Advantageously, filler particles of the above mentioned type may be implemented in a composite used in combination with one or more functional bodies for constituting an electronic device. Due to their adhesion enhancing function, the filler particles may also reliably prevent the risk of crack formation within the composite or electronic device. This may significantly improve the mechanical integrity of the composite and consequently of the electronic device as a whole. Advantageously, a morphological adhesion promoter at an exterior surface of filler particles does not influence the electrical properties of a composite or an electronic device with such filler particles in an undesired way. Beyond this, a morphological adhesion promoter on a surface of filler particles may provide excellent adhesion promoting properties even at elevated temperature and/or in the presence of humidity. The mentioned advantageous properties of filler particles according to an exemplary embodiment in terms of high-temperature behaviour, behaviour in humid environment, and electric inertness cannot always be obtained with chemical adhesion promoters. Apart from this, filler particles with morphological adhesion promoter at an exterior surface may additionally promote an improved particle-to-particle adhesion. Moreover, filler particles of a composite material may allow so adjust the physical and special chemical properties of the composite material, for instance in terms of thermal conductivity, coefficient of thermal expansion, flow behaviour, etc. Exemplary embodiments may combine such a functional fine-tuning of a composite with a highly reliable intra-composite adhesion.

### DESCRIPTION OF FURTHER EXEMPLARY EMBODIMENTS

In the following, further exemplary embodiments of the filler particle, the composite, the electronic device, and the methods will be explained.

In the context of the present application, the term “filler particles” may particularly denote a (in particular powderous or granulate-type) substance filling out interior volumes in a surrounding medium such as a matrix. By the selection of the filler particles, the physical and/or chemical properties of the composite can be adjusted. Such properties may include the coefficient of thermal expansion, the thermal conductivity, the dielectric properties, etc. The filler particles may thus be added so as to fine tune the physical, chemical, etc., properties of the composite, for example an encapsulant. For instance, the filler particles may increase thermal conductivity of the composite so as to efficiently remove heat out of an interior of an electronic device such as a package (such heat may be generated by an electronic component, for instance when embodied as power semiconductor chip). It is also possible that the filler particles provide an improved dielectric decoupling between such an electronic component and the surrounding of the package.

In the context of the present application, the term “core” may particularly denote a central body or part of a filler particle. Such a core may be a single body or may be an arrangement of a plurality of connected bodies. The core may be spatially separated, partially or entirely, from an exterior of the respective filler particle, at least partially by the shell of the respective filler particle.

In the context of the present application, the term “shell” may particularly denote an exterior portion or outer structure of a respective particle, which may be at least partially arranged on the core. The connection between shell and core may be direct, i.e. without an additional structure in between, or indirectly, i.e. with at least one additional structure in between. The shell may be a coating of the core, and may thus be made for example of another material than the core. It is however also possible that the shell is made of the same material as the core, however may have an adapted material property for increasing the surface area per volume of the shell compared with the core. In the latter mentioned embodiment, shell and core may for instance differ from each other (in particular only) concerning density (which may be smaller for the shell as compared to the core) and/or porosity (which may be larger for the shell as compared to the core), but not concerning material.

In the context of the present application, the term “adhesion promoter” may particularly denote any material and/or measure enhancing adhesion. More specifically, such an adhesion promoter provided by the shell may act as an interface between the core of the filler particles and a surrounding matrix or medium.

In the context of the present application, the term “morphological adhesion promoter” may particularly denote an adhesion promoter having a morphological structure. In the context of the present application, the term “morphological structure” may particularly denote a structure having a topology and/or porous structure and/or being shaped in such a way so as to increase the connection surface with connected material of filler particles and surrounding matrix to thereby promote adhesion. Moreover, the morphology of a morphological adhesion promoter may cause an advantageous mechanical interlocking between material of the surrounding matrix and material of the morphological adhesion promoter of the filler particles' shell on the other hand. In other words, a morphological structure promotes adhesion due to its shape, rather than only promoting adhesion due to its chemistry. However, it is also possible that a morphological structure is synergistically made of material which, in view of its intrinsic properties, promotes adhesion additionally to the shape. In particular, a morphological adhesion promoter may be a porous material. A specific shaping and in particular increase of the interior surface of the adhesion promoter may enhance adhesion between filler particles and surrounding matrix or medium, mediated by the morphological adhesion promoter.

In the context of the present application, the term “composite” or composite material may particularly denote a material which is produced from two or more constituent materials, in particular including at least filler particles and surrounding matrix. These constituent materials may have dissimilar chemical and/or physical properties and may be merged or mixed to create a composite material with properties unlike the individual constituent materials. Within the finished composite material, the individual constituent materials may remain separate and distinct. For example, the composite may be an encapsulant.

In the context of the present application, the term “matrix” may particularly denote a liquid, viscous, or solid medium or matter to be merged or mixed with the filler particles. In particular, the matrix may be and/or may comprise a curable liquid or flowable medium and/or a slurry. The matrix may become solid upon curing. For instance, the matrix may comprise a resin such as an epoxy resin.

In the context of the present application, the term “electronic device” may particularly denote a structure, body or arrangement of a plurality of structures and/or bodies fulfilling an electric or electronic function. In particular, such an electronic device may be configured for enabling a controlled flow of electric current and/or electric signals. For example, the electronic device is a package, in particular a semiconductor package comprising at least one encapsulated semiconductor component.

In the context of the present application, the term “functional body” may in particular denote any constituent or member of the electronic device contributing to the electronic function of the electronic device. Such a functional body may for instance be an encapsulated electronic component, such as a semiconductor chip. Another example for a functional body is a carrier carrying an electronic component, for instance a leadframe-type carrier. Yet another example for a functional body is an electrically conductive connection structure, such as a clip or a bond wire, used for connecting an electronic component with a carrier.

A gist of an exemplary embodiment is the manufacture as well as the use of filler particles (for example filler spheres and/or filler fibers) that have a dense inner core (for example similar to conventional mold compound filler particles) with a porous adhesion layer on the outside as an example of a shell configured as morphological adhesion promoter. Advantageously, such a porous adhesion promoter may be configured to interact with a surrounding matrix (in particular a resin) via mechanical interlocking. For instance, the composite comprising filler particles and matrix may be a mold compound. During and after a molding process, the morphological adhesion promoter at the exterior surface of the filler particles may promote the adhesion between the filler particles and the matrix in form of a mold compound resin.

In an embodiment, the composite comprises a matrix, wherein the filler particles are embedded in the matrix. The interaction between the morphological adhesion promoter of the shells of the filler particles and the surrounding matrix material may improve the intra-composite adhesion and may thereby enhance the mechanical integrity of the composite as a whole.

In an embodiment, the matrix comprises a resin, in particular a polymer resin. For example, such a polymer resin may be an epoxy resin. A corresponding composite may be used for example as an encapsulant for encapsulating one or more constituents of a package such as a semiconductor chip package.

In an embodiment, the core is formed of a dense solid material. In particular, the core may be made of a non-porous material. Preferably, the core may have a larger density than its surrounding shell. Consequently, a percentage of void or hollow volume of a core may be smaller than the corresponding percentage for the shell which at least partially surrounds said core. Hence, the function of the filler particles (for instance enhancing thermal conductivity) may be dominated by the core, whereas the shell may enhance adhesion with surrounding matrix material.

In an embodiment, the morphological adhesion promoter is a porous material. In other words, the morphological adhesion promoter may have a pronounced porosity. In particular, porosity of the shell may be larger than of the core. Porosity or void fraction may be a measure of the void or empty spaces in a material, and may be calculated as a fraction of the volume of voids over the total volume. For instance, porosity of the morphological adhesion promoter may be at least 5%, preferably at least 30%. In contrast to this, porosity of the core may be less than 1%, in particular 0.

In an embodiment, the filler particle is free of a chemical adhesion promoter, in particular is free of silane. Conventional filler particles with chemical adhesion promoters such as silane may have a limited effect on the enhancement of adhesion, in particular at higher temperature and/or in the presence of humidity. Beyond this, chemical adhesion promoters may deteriorate the electric behaviour of filler particles in an undesired way. Furthermore, the supply of a chemical adhesion promoter to the filler particles may involve additional procedural complexity and effort. Preferably, the described embodiment avoids any extra processes in terms of provision of the chemical adhesion promoter.

However, alternative embodiments may provide a combination of a morphological adhesion promoter by a corresponding configuration of the shells with the additional formation of a chemical adhesion promoter, to further enhance adhesion.

In an embodiment, at least part of a set of filler particles has a shape of a group consisting of beads, plates, fibers, solid spheres, hollow spheres, tubes, and multi-tubes. However, any other shape and/or any combination of the mentioned and/or other shapes of the filler particles may be possible as well.

In an embodiment, the filler particle has a hollow core. For instance, at least some of the filler particles may be spheres with an interior macroscopic hole. Such a configuration may for instance be advantageous when a low weight of the composite material is desired.

In another embodiment, the filler particle has a void-free core. Such filler particles with dense or solid core without macroscopic interior holes may provide a particularly pronounced particle function, for instance an efficient increase of the thermal conductivity of the composite in comparison with the absence of filler particles.

In an embodiment, different ones of the filler particles are directly physically connected with each other. Advantageously, a porous and dendritic adhesion promoter layer of a shell of the filler particles can efficiently interact within a composite with other filler particles of the same type. Descriptively speaking, the interconnection between overlapping porous shells of different filler particles may function in a similar way as in a Velcro fastener. Advantageously, this particle-particle interaction may additionally improve the intra-composite adhesion.

In an embodiment, material of the matrix fills at least part of pores of interconnected shells in a connection region of connected particles. Where the interaction or interconnection between neighboured filler particles of a composite is relatively weak, weakly coupled porous shells of adjacent filler particles may be additionally filled with matrix material, for instance resin which flows into such pores. Also this enhances the mechanical interlocking within the composite and thereby improves the mechanical integrity.

In an embodiment, at least a portion of interconnected shells in a connection region of connected filler particles is free of material of the matrix, and is in particular substantially void-free. In case of a small mutual distance between neighboured filler particles of the composite, the porous shells may overlap to such a degree that the shells strongly interconnect substantially or entirely without any remaining voids in between. Descriptively speaking, such shells of closely coupled neighboured filler particles may enter into a merged or fusion connection and may form an integral structure without matrix material in between. Such a strong particle-particle connection may further improve the intra-composite adhesion forces. The mentioned pronounced particle-particle interaction can be triggered by a sufficiently large selection of the filler particle-to-matrix ratio (in particular weight or volume ratio), since this ratio has an impact on the average particle-to-particle distance in the composite.

In an embodiment, the shells of the filler particles mechanically interlock filler particles with the matrix and/or filler particles with each other. Thus, in particular the porous character of the shells may result in interlocking and consequently a pronounced mechanical link between a respective filler particle and the surrounding matrix and/or between neighboured filler particles.

In an embodiment, the composite or composite material is an encapsulant. In the context of the present application, the term “encapsulant” may particularly denote an electrically insulating material surrounding at least part of a constituent (such as an electronic component and/or at least part of a carrier) of an electronic device to provide mechanical protection, electrical insulation, and optionally a contribution to heat removal during operation. For instance, the encapsulant may be a mold compound and may be created for example by transfer molding. Alternatively, the encapsulant may be a casting compound formed by casting.

In other embodiments, the composite may be configured for example as a laminate, a cement, or a ceramic composite. A laminate may be a sheet which may be interconnected with one or more other bodies (in particular layers) by lamination. For instance, such a laminate may be used for manufacturing printed circuit boards (PCBs). Also a cement may be used for interconnecting constituents of an electronic device. Moreover, a ceramic composite may for instance be used for manufacturing a casing or casing part of an electronic component, or even for encapsulation.

In an embodiment, the at least one functional body comprises at least one of the group consisting of a carrier for carrying an electronic component, an electronic component, and an electrically conductive coupling element for electrically coupling an electronic component with a carrier. Within corresponding package-type electronic devices, conventional tendencies of delamination may be strongly suppressed thanks to the improved adhesion within the electronic device by the morphological adhesion promoter of the shells.

In an embodiment, the electronic device is a package (for instance a semiconductor package), in particular a power module such as a semiconductor power package. In the context of the present application, the term “package” may particularly denote an electronic device comprising one or more electronic components packaged using an encapsulant. Optionally, also a carrier for the electronic component and/or one or more electrically conductive coupling elements (such as bond wires or clips) may be implemented in a package.

In an embodiment, the method comprises forming the shell by pyrolytic deposition, in particular of porous metal oxides out of metalorganic molecules. Pyrolysis may denote in particular the thermal decomposition of materials at elevated temperatures in an inert atmosphere which may involve a change of chemical composition. Pyrolysis may be advantageously used for depositing porous shell material on cores of filler particles. In such an embodiment, the morphological adhesion promoter may hence be produced by a pyrolytic deposition of porous metal oxides on the basis of metalorganic molecules.

In an embodiment, the method comprises forming the shell by Atomic Layer Deposition (ALD), in particular of porous metal oxides. ALD may denote a thin-film deposition technique based on the sequential use of a gas-phase chemical process. For instance, ALD reactions may use different chemicals as precursors or reactants which may react with the surface of a material so that a thin film is deposited through repeated exposure to separate precursors. Advantageously, it turned out as possible to produce morphological adhesion promoters by Atomic Layer Deposition of metal oxides.

In an embodiment, Chemical Vapor Deposition (CVD) or Physical Vapor Deposition (PVD) may be used as well for forming the shell.

Advantageously, the method can also include a two stage process of first forming a uniform, flat layer, for example of a metal oxide, by ALD, CVD, PVD, and a consecutive stage to apply a certain porosity to the formed layer (for example with a hot water treatment).

In an embodiment, the method comprises forming the shell by selective and/or anisotropic etching of a surface of a preform of the core, in particular a preform of a silicon oxide (SiO₂) core. Selective etching of the surface of the filler particles may also promote formation of a morphological adhesion promoter at the shells. For example, this may be accomplished by etching of silicon oxide particles with a chemistry ensuring an anisotropic etching behaviour through sidewall protection.

In an embodiment, the method comprises forming the shell by hot medium treatment of a preform of the core, in particular a preform of an aluminum oxide (Al₂O₃) core, for conversion into dendrites. For example for aluminum oxide filler particles, hot-water treatment may be carried out to trigger a conversion into a shell-like dendritic structure on the surface of the filler particles, i.e. at their shells.

In an embodiment, the method comprises forming a dendritic shell on the core or in a preform of the core, and connecting the dendritic shells of different filler particles with each other. Dendrites may denote microporous structures. Consequently, dendrites of adjacent shells of adjacent filler particles may be highly prone to mutual interaction in view of their excellent adhesion properties. For example, connection of the dendritic shells with each other may be accomplished by at least one of the group consisting of compression and interdiffusion. Descriptively speaking, compression may reduce the mutual distance between adjacent shells, so that the shells may be brought in interaction with each other. Interdiffusion may denote the phenomenon of diffusion of two different atomic types from formerly separate areas into each other.

In an embodiment, the filler particles (for instance all or at least 80% or at least 90% of the filler particles) have a diameter in a range from 10 nm to 10 μm, in particular in a range from 20 nm to 2 μm, more particularly in a range from 50 nm to 1 μm. In an embodiment, even larger filler particles can be in the composite, in particular when used as mold compound. Thus, filler particles in a mold compound-type composite may be even larger, for instance up to 140 μm. Thus, there can be larger filler particles in the resin. It is however possible to use mixtures with filler particles that are smaller down to the values listed above.

In an embodiment, the filler particles have a homogeneous diameter. In other words, different filler particles may all have essentially the same dimensions. Alternatively and preferably, the filler particles may however have a diameter distribution. When being provided with a diameter distribution rather than a homogeneous diameter, the filler particles may show an even better adhesion between matrix and shell and/or between shells of different filler particles.

In an embodiment, the filler particles have a value of the coefficient of thermal expansion (CTE) selected so that the presence of the filler particles in the matrix reduces a mismatch between the coefficients of thermal expansion between the composite and the at least one functional body compared with an absence of the filler particles in the composite. In other words, a CTE mismatch between composite and functional body may be reduced. As a consequence, thermal stress due to different thermal expansions upon temperature changes may be reduced.

In an embodiment, the composite is a mold compound. A mold compound may comprise a matrix of flowable and hardenable material and filler particles embedded therein. For instance, filler particles may be used to adjust the properties of the mold component. In particular, this adjustment may be made to enhance thermal conductivity, to adapt the coefficients of thermal expansion (CTE) and/or to increase the flexural strength.

In an embodiment, the at least one functional body comprises a carrier. In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad.

In an embodiment, the at least one functional body comprises an electronic component. The electronic component may be mounted on a carrier. In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc.

In an embodiment, the at least one functional body comprises an electrically conductive coupling element electrically coupling the electronic component with the carrier. Such an electrically conductive coupling element may be a clip, a bond wire or a bond ribbon. A clip may be a curved electrically conductive body accomplishing an electric connection with a high connection area to an upper main surface of a respective electronic component. Additionally or alternatively to such a clip, it is also possible to implement one or more other electrically conductive interconnect bodies in the package, for instance a bond wire and/or a bond ribbon connecting the electronic component with the carrier or connecting different pads of an electronic component.

In an embodiment, the morphological adhesion promoter comprises at least one of the group consisting of a metallic structure, an alloy structure, a chromium structure, a vanadium structure, a molybdenum structure, a zinc structure, a manganese structure, a cobalt structure, a nickel structure, a copper structure, a flame deposited structure, a roughened metal structure (in particular a roughened copper structure or a roughened aluminum oxide structure), and any oxide, nitride, carbide, and selenide of any of said structures. All structures may comprise or consist of these metals and/or the alloys thereof. In addition, these structures may comprise or consist of these metals and their alloy-oxides. In particular, single oxides and mixed oxides are possible in different embodiments. Whether the alloy oxidizes or not may depend on the thermal budget in production. However, other materials and structures may be used for the morphological adhesion promoter as well. The above-mentioned flame deposited structure may comprise or consist of silicon dioxide, any titanium oxide (such as for instance TiO₂, TiO, TiₓO_{y}), etc. Any organometallic precursor can be used that can be burned in a mixture with a burning gas such as propane or butane and form the specific metal oxide.

In particular, a morphological adhesion promoter may be formed at an exterior surface of the filler particles using Atomic Layer Deposition (ALD), Chemical Vapor Deposition (CVD), etc.

In an embodiment, recesses of the morphological adhesion promoter of the shell of the filler particles may comprise at least one of the group consisting of pores, dendrites, and gaps between islands. However, other kinds of openings can be formed as well as long as they increase the surface of the morphological adhesion promoter and promote mechanical interlocking between filler particles and composite matrix.

In an embodiment, the filler particles are selected from a group consisting of crystalline silica, fused silica, spherical silica, titanium oxide, aluminium hydroxide, magnesium hydroxide, zirconium dioxide, calcium carbonate, calcium silicate, talc, clay, carbon fiber, glass fiber and mixtures thereof. Other filler materials are however possible depending on the demands of a certain application. Filler particles (for example SiO₂, Al₂O₃, Si₃N₄, BN, AlN, diamond, etc.), for instance for improving thermal conductivity may be used as well. In particular, organic particles may be used as fillers (for instance, fillers can also comprise or consist of polymers or polymer mixtures, such as: epoxies, polyethylene, polypropylene, etc.). In particular, filler particles may be provided as nanoparticles or microparticles. Filler particles may have identical dimensions or may be provided with a distribution of particle sizes. Such a particle size distribution may be preferred since it may allow for an improved filling of gaps in an interior of the encapsulant. For instance, the shape of the filler particles may be randomly, spherical, cuboid-like, flake-like, and film-like. The filler particles can be modified, coated, and/or treated as to improve the adhesion and/or the chemical binding to the surrounding matrix. Examples are silanes. A coating can also change the surface energy of the fillers and may thereby improve and enable the wetting of the solution/the matrix.

In an embodiment, the package comprises a carrier on which an electronic component is mounted. For instance, such a carrier may be a leadframe (for instance made of copper), a DAB (Direct Aluminum Bonding), DCB (Direct Copper Bonding) substrate, etc. Also at least part of the carrier may be encapsulated by the encapsulant, together with the electronic component.

In an embodiment, the method comprises pre-treating at least part of the electronic component, carrier and/or electrically conductive coupling element for promoting adhesion between the composite and at least part of the electronic component, carrier and/or electrically conductive coupling element. Thus, the adhesion between the above-described composite and the functional body may be improved by applying an adhesion promoting additional device-level treatment. Highly advantageously, it is possible to pre-treat the package or part thereof (for instance a metallic surface thereof) so as to improve its adhesion properties with regard to the above-described composite. For instance, it is possible to carry out a surface activation of the surface of the package or a part thereof to be encapsulated by the composite. Such a surface activation may be accomplished, for instance, by a plasma treatment of the respective surface, in particular of the respective metallic surface.

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts (in particular fully compatible with standard TO packaging concepts) and appears externally as a conventional package, which is highly user-convenient.

In an embodiment, the package is configured as power module, for instance molded power module such as a semiconductor power package. For instance, an exemplary embodiment of the package may be an intelligent power module (IPM). Another exemplary embodiment of the package is a dual inline package (DIP).

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

As substrate or wafer forming the basis of the electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

Furthermore, exemplary embodiments may make use of semiconductor processing technologies such as appropriate etching technologies (including isotropic and anisotropic etching technologies, particularly plasma etching, dry etching, wet etching), patterning technologies (which may involve lithographic masks), deposition technologies (such as Chemical Vapor Deposition (CVD), Plasma Enhanced Chemical Vapor Deposition (PECVD), Atomic Layer Deposition (ALD), sputtering, etc.).

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

In conventional mold compounds, the interaction between filler particles and the resin is usually done by the use of organic adhesion promoters such as silanes, which are added as filler coating, coupling agents or adhesion promoters. However, chemical adhesion promoters can have several disadvantages, such as a low temperature stability, a negative influence on dielectric properties (for instance dielectric constant) and corrosion instability.

Therefore, alternative ways to improve the interaction adhesion between fillers and the resin would be beneficial.

According to an exemplary embodiment, a set of a plurality of filler particles is provided, wherein each of said filler particles has a central core at least partially surrounded by a shell with morphological adhesion properties. For instance, a porous coating may be formed on a core of filler particles. Such filler particles are particularly appropriate for composites, which may comprise at least one further material such as a matrix (for instance comprising a resin) in which the filler particles may be embedded. The described filler particles according to an exemplary embodiment may show excellent properties in terms of adhesion with matrix material as well as concerning adhesion with other filler particles. Descriptively speaking, the increased contact surface of the morphological adhesion promoter of the shells of the filler particles may increase the adhesive strength and may also have a catalytic function. Advantageously, the pronounced adhesion may also be obtained at temperatures significantly above room temperature, and in a humid environment. Further advantageously, the filler particles with morphological adhesion promoter do not influence the electric properties of a composite or an electronic device in which the filler particles are implemented.

What concerns the improved particle-particle adhesion provided by filler particles according to an exemplary embodiment, shells of adjacent filler particles may mechanically interlock with each other. In embodiments, adjacent filler particles may even experience interdiffusion into each other (for instance in the presence of porous metal). Advantageously, such interdiffusion may already occur at moderate temperatures far below melting temperature. The described particle-particle interaction may even result in resin-free interfaces between interconnected filler particles.

Exemplary applications of exemplary embodiments in particular include encapsulants (such as a mold compound, cements and inorganic polymers), silicones for power modules, electrically insulating or electrically conductive glue, underfill materials, polyimide for passivation, and laminates for printed circuit boards. In such laminates, the filler particles may improve adhesion between glass fibers (as filler particles) and epoxy resin (as matrix).

Exemplary embodiments relate to the production as well as to the use of filler particles (such as filler spheres or filler fibers) that have a dense inner core with a porous adhesion shell or layer on the outside functioning as morphological adhesion promoter. The filler particles may have any kind of geometries including plates, fibers, hollow spheres, tubes, multi-tubes, etc. For instance, such filler particles may be used in mold compounds and other composite materials (for instance for PCBs, plastics, cements, etc.).

The morphological adhesion promoter of the shells, in particular embodied as porous adhesion layer, can act in particular in two ways: Firstly as porous layer and particle surface interacting with matrix (for instance resin) material. Secondly, as porous layer and particle surface interacting with other filler particles. Descriptively speaking, this may be denoted as a Velcro-like function.

According to an exemplary embodiment, a proper interaction of the filler particles and the material the matrix (in particular resin) may be provided to ensure good material properties in composite materials comprising a polymer matrix and filler particles (for example for mold compounds). Material properties such as the flexural strength, thermal conductivity and breakdown voltage are just some parameters that may be positively influenced by the obtainable good resin to filler interaction.

According to an exemplary embodiment, a porous adhesion promoter is provided which is configured to interact with resin or other matrix material via mechanical interlocking. Advantageously, the porosity of the morphological adhesion promoter may in particular allow a mechanical interlocking with mold compound during the molding process (and to some extent already during an extruder process during manufacturing).

In the following, various embodiments of manufacturing filler particles with morphological adhesion promoter of a shell will be explained. In particular, a desired mechanical interlocking can be achieved with such morphological adhesion promoters:

1) Pyrolytic Deposition, for Instance of Porous Metal Oxides Out of Metalorganic Molecules

In this embodiment, a method of manufacturing filler particles may comprise forming the shell by pyrolytic deposition, in particular of porous metal oxides out of metalorganic molecules. During such a manufacturing process, the filler particles can be guided through a horizontal deposition flame and then fall down into a collection compartment. Such a pyrolytic deposition may be carried out for example under normal pressure or under vacuum conditions. The pyrolytic deposition may be carried out, for example, using Chemical Vapor Deposition (CVD).

2) Atomic Layer Deposition (ALD), for Instance of Metal Oxides

In this embodiment, a method of manufacturing filler particles may comprise forming the shell by Atomic Layer Deposition, in particular of porous metal oxides. Hence, it may be possible to execute ALD on powder, which may be in particular advantageous for the case of thin-film powder. This may be accomplished so that the precursor gas can sufficiently diffuse through the powder layer to enable coating of all filler particles. In some embodiments, an additional treatment of the deposited ALD layer can be beneficial to generate the morphological adhesion promotor (for example by hot water treatment).

3) Selective Etching of the Particle Surface

In this embodiment, a method of manufacturing filler particles may comprise forming the shell by selective and/or anisotropic etching of a surface of a preform of the core, in particular a preform of a silicon oxide core. For example, etching of silicon oxide (SiO₂) particles may be carried out with a chemistry with anisotropic etching behavior. For example, this may be achieved through sidewall protection.

Formation of a morphological adhesion promoter at an exterior shell of filler particles may also be accomplished by selectively etching exposed particle material at grain boundaries. For instance, copper material is appropriate for this purpose. A roughened or porous copper surface may be created in this way and may be used as exterior morphological adhesion promoter.

4) Water Treatment, in Particular Hot Water Treatment

In this embodiment, a method of manufacturing filler particles may comprise forming the shell by hot medium treatment of a preform of the core, in particular a preform of an aluminum oxide core, for conversion into dendrites. In particular for filler particles of aluminum oxide (Al₂O₃), hot-water treatment may be executed to trigger conversion into a shell-like dendritic structure on the surface. Hot-water treatment may be carried out with condensed water or with water vapor. For instance, aluminum oxide can be rendered morphological by hot-water treatment, for instance for some minutes. For example, a slurry of filler particles can be immersed in hot water, followed by a filtration to remove water. A temperature of the water may be at least 20° C., in particular at least 80° C., for example up to 500° C. It is also possible to carry out hot-water treatment by ALD, for instance using a water concentration of at least 10 ppm.

In yet another embodiment, water treatment of filler particles for creating a morphological adhesion promoter may be done with cold water, for instance having a temperature of at least 0° C.

5) Other Deposition Techniques

Laser-assisted Physical Vapor Deposition (PVD) and Plasma Enhanced Chemical Vapor Deposition (PECVD) are further options for creating a morphological adhesion promoter on an exterior shell of filling particles.

Also a galvanic deposition on filling particles may create a morphological adhesion promoter at an exterior surface. For instance, silver particulates may be galvanically deposited. Furthermore, electroless deposition (for instance of nickel oxide) on filling particles is an option. If desired or required, the filling particles may be subsequently post-treated for enhancing porosity, for instance by chemically etching.

6) Chemical Reduction

For example, iron oxide may be reduced to porous iron by executing a gas phase reaction. If desired or required, a post treatment with an appropriate acid may be carried out, for instance using formic acid.

7) Formation of a Porous and Dendritic Adhesion Promoter Layer on Filler Particles for Interaction with Other Filler Particles

In this embodiment, a method of manufacturing filler particles may comprise forming a dendritic shell on the core or in a preform of the core, and connecting the dendritic shells of different particles with each other. In particular, this may comprise connecting the dendritic shells with each other by at least one of the group consisting of compression and interdiffusion. Such a porous or dendritic layer, as morphological adhesion promoter shell, can be adapted in a way that the porous layers of the filler particles can directly interact with other filler particles upon compression (for example similar to a Velcro fastener). That way, the contact area between two filler particles may not consist of pure resin, but of a porous inorganic coating layer, where the pores may be filled with resin. In this way, a material with very high flexural strength, high thermal conductivity, appropriate comparative tracking index, etc. can be established.

The interaction also can be accomplished via interdiffusion of the dendritic adhesion promoter layers to get a compact inorganic interconnect between two filler particles. This means that there may be no interface between organic matrix and inorganic particle anymore at the contact point of two particles. Preferably, a crystalline and strong interconnect between two filler particles may be created without any interface to a resin of the matrix.

A porous interface design to solve adhesion between the filler particles or towards the resin with mechanical interlocking may also improve high temperature reverse bias (HTRB) stability, in particular when dedicated adhesion promoter molecules (such as silane) are omitted. Additionally, with this also ion contamination induced failures may be omitted as the interface between filler particles and resin may be enlarged and diffusion paths may become much longer for ions such as sodium or potassium.

Exemplary embodiments can be useful in particular in molded packages. Moreover, filler particles according to an exemplary embodiment may also be used for housing materials for frame modules. Furthermore, filler particles according to an exemplary embodiment may be a proper option for filler particles used in silicone gels (for example for modules), since silicone gels may suffer from poor adhesion. Such a shortcoming may be improved by the mechanical interlocking of a morphological adhesion promoter shell according to an exemplary embodiment. Apart from this, also cement and polymer ceramic materials may strongly profit from exemplary embodiments.

Hence, exemplary embodiments may be used in many different technical fields, for instance the cement industry. Particularly preferred may be embodiments in which the filler particles are used for epoxy mold compounds, in particular drift free epoxy mold compounds. Furthermore, inorganic mold compounds, high lambda mold compounds, chlorine mitigating mold compounds, and high voltage mold compounds may be other possible embodiments.

In general, exemplary embodiments may be advantageously implemented for all package materials, especially mold compounds. Since a high thermal conductivity may be achieved by exemplary embodiments, package cooling can be achieved by at least partially cooling through a mold compound comprising filler particles according to an exemplary embodiment.

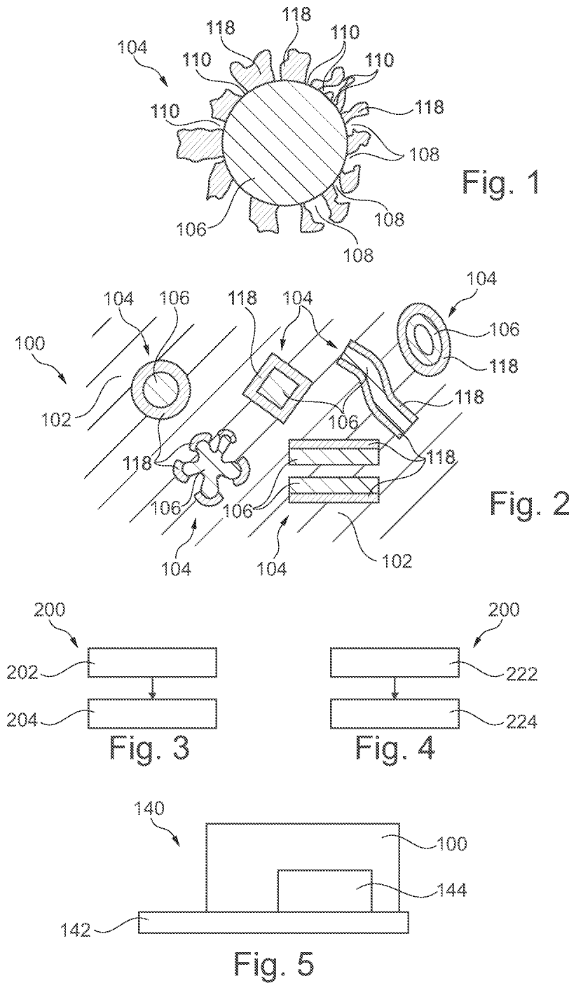

FIG. 1 illustrates a filler particle 104 according to an exemplary embodiment.

The cross-sectional view of FIG. 1 illustrates a filler particle 104 for a composite 100 (see for instance FIG. 2). As shown, the filler particle 104 comprises a core 106. Furthermore, the filler particle 104 comprises a shell 118 which covers the core 106 and has a morphological adhesion promoter 108. The latter may be formed using pores 110 extending partially or entirely through the shell 118.

FIG. 2 illustrates a composite 100 according to an exemplary embodiment.

The cross-sectional view of FIG. 2 illustrates a composite 100 which comprises a matrix 102 in which a plurality of filler particles 104 are embedded. As shown, each of the filler particles 104 comprises a core 106 being partially or entirely coated by a shell 118 having a morphological adhesion promoter 108 (not shown in FIG. 2, compare FIG. 1). In FIG. 2, the different filler particles 104 have different shapes.

FIG. 3 illustrates a flowchart 200 of a method of manufacturing filler particles 104 for a composite 100 according to an exemplary embodiment. The reference signs used for the description of FIG. 3 also relate to the embodiment of FIG. 1.

As shown in a block 202, the method comprises at least partially covering a core 106 of each of the filler particles 104 by a shell 118.

Corresponding to block 204, the method further comprises forming the shell 118 with a morphological adhesion promoter 108.

FIG. 4 illustrates a flowchart 220 of a method of manufacturing a composite 100 according to an exemplary embodiment. The reference signs used for the description of FIG. 4 also relate to the embodiment of FIG. 2.

As shown in a block 222, the method comprises manufacturing filler particles 104 by carrying out a method of manufacturing filler particles 104 having the features of flowchart 200 according to FIG. 3.

Corresponding to block 224, the method further comprises embedding the filler particles 104 in a matrix 102.

FIG. 5 illustrates an electronic device 140 according to an exemplary embodiment.

The illustrated cross-sectional view of electronic device 140 comprises two functional bodies 142, 144 and a composite 100 (compare for example FIG. 2) comprising filler particles 104 according to FIG. 1 and covering respective parts of the functional bodies 142, 144.

Electronic device 140 according to FIG. 5 is a package comprising a carrier, corresponding to functional body 142, and an electronic component, corresponding to functional body 144, mounted on the carrier. Composite 100 is here embodied as an encapsulant which at least partially encapsulates the functional bodies 142, 144.

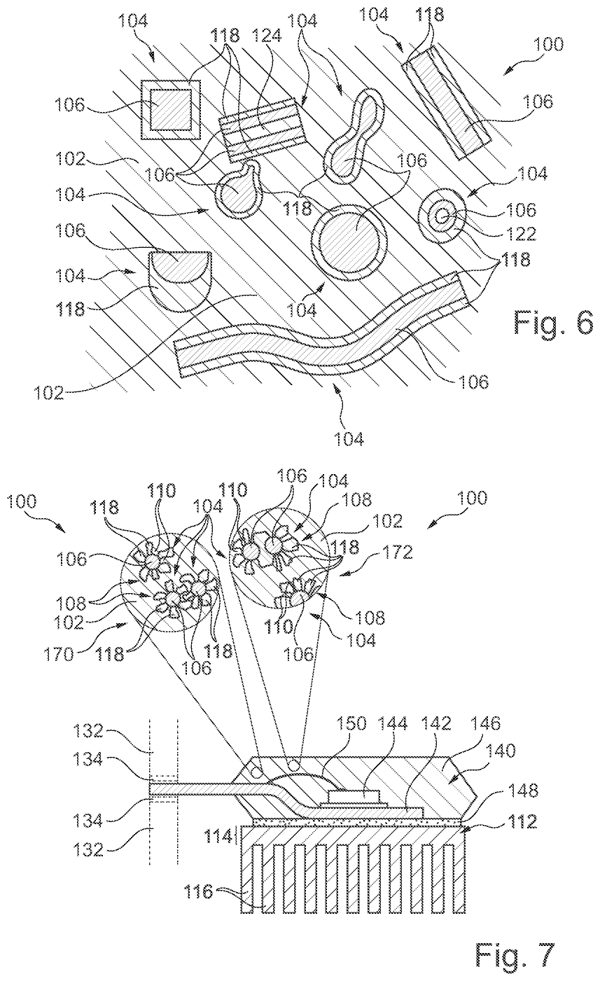

FIG. 6 illustrates a composite 100 with filler particles 104 embedded in a matrix 102 according to an exemplary embodiment.

The composite 100 shown in FIG. 6 may be embodied as a mold compound for encapsulating an electronic component of a package (see FIG. 7). The illustrated composite 100 comprises a matrix 102 which comprises, in turn, a resin such as an epoxy resin or another polymer resin. Filler particles 104 of different shapes, types and dimensions are embedded in the matrix 102 for increasing the thermal conductivity of the composite 100 in comparison with a scenario without filler particles 104. As will be described in the following in detail, the filler particles 104 are configured for enhancing adhesion with the matrix 102. When cured, the composite 100, for instance when being implemented in a semiconductor power package, may show a strong adhesion between its constituents, may prevent delamination and may also prevent formation of cracks.

As shown, each of the filler particles 104 comprises a core 106 which is partially or entirely coated by a respective shell 118. As shown, different filler particles 104 and correspondingly their cores 106 may have the shape of beads, plates, fibers, solid spheres, hollow spheres, tubes (which may have a central through hole 124), etc. Shape and dimension of the filler particles 104 may be selected in accordance with their intended technical functions in the framework of the composite 100.

Advantageously, each shell 118 has a morphological adhesion promoter 108 at least at its exterior surface (compare FIG. 1 and FIG. 7). Although not shown in FIG. 6, the morphological adhesion promoter 108 of the shells 118 may be a porous material. In view of their morphological adhesion promoting configuration, the shells 118 mechanically interlock filler particles 104 and the matrix 102 with each other. Since the configuration of the shells 118 provides a strong morphological adhesion promoting function to the filler particles 104, the filler particles 104 may be free of a chemical adhesion promoter, such as silane. This configuration may ensure a strong adhesion within the composite 100 over a broad temperature range (including high temperatures) and even in the presence of humidity. Advantageously, the purely geometric morphological adhesion promoter 108 does not influence the electric properties of the composite 100, contrary to conventional approaches with chemical adhesion promoters.

Each of the cores 106 is formed of a dense solid non-porous material. Thereby, the cores 106 may properly fulfil their actual technical function, for instance to enhance thermal conductivity, to adjust the coefficient of thermal expansion, to set dielectric properties, etc. A part of the filler particles 104 may have a hollow core 106, i.e. a core 106 with an interior void 122. Another part of the filler particles 104 may have a void-free core 106.

FIG. 7 illustrates a cross-sectional view of a package as an example of an electronic device 140 according to an exemplary embodiment. The electronic device 140 is mounted on a mounting structure 132, here embodied as printed circuit board.

The mounting structure 132 comprises an electric contact 134 embodied as a plating in a through hole of the mounting structure 132. When the electronic device 140 is mounted on the mounting structure 132, an electronic component 144 of the electronic device 140 is electrically connected to the electric contact 134 via an electrically conductive carrier 142, here embodied as a leadframe made of copper.

The electronic device 140 thus comprises the electrically conductive carrier 142, the electronic component 144 (which is here embodied as a power semiconductor chip) mounted on the carrier 142, and an encapsulant 146 encapsulating part of the carrier 142 and the electronic component 144. Construction and function of encapsulant 146 will be described below in further detail.

As can be taken from FIG. 7, a pad on an upper main surface of the electronic component 144 is electrically coupled to the carrier 142 via a bond wire as electrically conductive coupling element 150. Alternatively, a clip may be used as electrically conductive coupling element 150 (not shown).

Reference signs 142, 144, 150 show different functional bodies of the electronic device 140.

During operation of the power electronic device 140, the power semiconductor chip in form of the electronic component 144 generates a considerable amount of heat. At the same time, it shall be ensured that any undesired current flow between a bottom surface of the electronic device 140 and an environment is reliably avoided.

For ensuring electrical insulation of the electronic component 144 and removing heat from an interior of the electronic component 144 towards an environment, an electrically insulating and thermally conductive interface structure 148 may be provided which covers an exposed surface portion of the carrier 142 and a connected surface portion of the encapsulant 146 at the bottom of the electronic device 140. The electrically insulating property of the interface structure 148 prevents undesired current flow even in the presence of high voltages between an interior and an exterior of the electronic device 140. The thermally conductive property of the interface structure 148 promotes a removal of heat from the electronic component 144, via the electrically conductive carrier 142 (of thermally properly conductive copper), through the interface structure 148 and towards a heat dissipation body 112. The heat dissipation body 112, which may be made of a highly thermally conductive material such as copper or aluminum, has a base body 114 directly connected to the interface structure 148 and has a plurality of cooling fins 116 extending from the base body 114 and in parallel to one another so as to remove the heat towards the environment.

The above-mentioned encapsulant 146 is a mold compound-type composite 100. As shown in details 170, 172 of FIG. 7, composite 100 comprises a matrix 102 of epoxy resin and filling particles 104 in the matrix 102.

Also referring to the above description of FIG. 6, the filler particles 104 of composite 100 may each comprise a core 106 and a shell 118 which covers or coats the core 106 and provides the function of a morphological adhesion promoter 108. While the cores 106 are formed of a dense solid non-porous material, the morphological adhesion promoter 108 exposed at an exterior side of the shells 118 is a porous material. Descriptively speaking, the porous morphological adhesion promoter 108 increases the contact area between a respective filler particle 104 and material of the matrix 102 in which the filler particle 104 is embedded. In view of the purely geometric adhesion promoting function of the shells 118, the filler particles 104 may be free of a chemical adhesion promoter such as silane.

In the embodiment of FIG. 7, the filler particles 104 are solid spheres. Depending on their function, they may have a different shape. The shells 118 may be spherical shells with a (for instance bifurcated) network of blind holes and/or through holes forming pores 110. The pores 110 of the shells 118 may be arranged in a random, statistic or stochastic manner (as shown in FIG. 1 and FIG. 7), or may be an ordered structure (not shown). In view of their porous configurations, some of the filler particles 104 shown in details 170, 172 may mechanically interlock with material (in particular resin) of matrix 102 flowing into the pores 110 in a non-cured state of the matrix material, or during curing. Thereby, the adhesion within the composite 100 may be improved.

As shown in details 170, 172 as well, some closely neighboured ones of the filler particles 104 are directly physically connected with each other, i.e. are in direct physical contact with each other.

Now referring to detail 170, two spatially close filler particles 104 are shown, wherein material of the matrix 102 fills pores 110 of interconnected shells 118 in a connection region of these connected particles 104.

Now referring to detail 172, two even closer filler particles 104 are shown having interconnected shells 118 in a connection region of these connected filler particles 104. In view of the very close spatial vicinity between the filler particles 102 shown in detail 172, an interconnection portion of the interconnected shells 118 is entirely free of resin material of the matrix 102. Said interconnection portion of the interconnected shells 118 is entirely void-free.

Hence, some of the shells 118 mechanically interlock particles 104 with the matrix 102 for promoting adhesion between particles 104 and matrix 102. Moreover, some of the filler particles 104 are mechanically interlocked with each other providing a further contribution to adhesion.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. Filler particle for a composite, wherein the filler particle comprises:
a core; and
a shell which at least partially covers the core and has a morphological adhesion promoter.

2. The filler particle according to claim 1, wherein the core is formed of a dense solid material.

3. The filler particle according to claim 1, wherein the morphological adhesion promoter comprises a porous material.

4. The filler particle according to claim 1, being free of a chemical adhesion promoter, in particular being free of silane.

5. The filler particle according to claim 1, comprising at least one of the following features:
wherein the filler particle has a void-free core;
wherein the filler particle has a hollow core;
wherein the filler particle has a shape of one of the group consisting of a bead, a plate, a fiber, a sphere, a tube, and a multi-tube.

6. An electronic device, comprising:
at least one functional body; and
a composite comprising filler particles according to claim 1 and covering or enclosing at least part of the at least one functional body.

7. The electronic device according to claim 6, wherein the composite comprises a matrix, in particular comprising a resin, and wherein the filler particles are embedded in the matrix.

8. The electronic device according to claim 6, wherein at least a part of the filler particles are directly physically connected with each other.

9. The electronic device according to claim 7, wherein material of the matrix fills at least part of pores of interconnected shells in a connection region of connected filler particles.

10. The electronic device according to claim 7, wherein at least a portion of interconnected shells in a connection region of connected filler particles is free of material of the matrix, and is in particular substantially void-free.

11. The electronic device according to claim 7, wherein the shells of the filler particles mechanically interlock filler particles with the matrix and/or filler particles with each other.

12. The electronic device according to claim 6, comprising at least one of the following features:
wherein the composite is configured as at least one of the group consisting of an encapsulant, in particular a mold compound, a laminate, a cement, and a ceramic composite;
wherein the at least one functional body comprises at least one of the group consisting of a carrier for carrying an electronic component, an electronic component, and an electrically conductive coupling element for electrically coupling an electronic component with a carrier.

13. The electronic device according to claim 6, configured as a package, in particular a semiconductor package, more particularly a semiconductor power package.

14. A method of manufacturing filler particles for a composite, wherein the method comprises:
at least partially covering a core of each of the filler particles by a shell; and
forming the shell with a morphological adhesion promoter.

15. The method according to claim 14, wherein the method comprises forming the shell by pyrolytic deposition, in particular of porous metal oxides out of metalorganic molecules.

16. The method according to claim 14, wherein the method comprises forming the shell by Atomic Layer Deposition, in particular of porous metal oxides.

17. The method according to claim 14, wherein the method comprises forming the shell by selective and/or anisotropic etching of a surface of a preform of the core, in particular a preform of a silicon oxide core.

18. The method according to claim 14, wherein the method comprises forming the shell by hot medium treatment of a preform of the core, in particular a preform of an aluminum oxide core, for creation of dendrites.

19. The method according to claim 14, wherein the method comprises forming a dendritic shell on the core or in a preform of the core, and connecting the dendritic shells of different filler particles with each other.

20. The method according to claim 19, wherein the method comprises connecting the dendritic shells with each other by at least one of the group consisting of compression and interdiffusion.
